(19) United States
(12) Patent Application Publication
(10) Pub. No.: US 2026/0130000 A1
(43) Pub. Date: May 7, 2026

(54) Method for Manufacturing Back Contact Cell Assembly

(71) Applicant: ZHEJIANG AIKO SOLAR TECHNOLOGY CO., LTD., Yiwu City (CN)

(72) Inventors: Zhigang XU, Yiwu City (CN); Xinqiang Yang, Yiwu City (CN); Cui Lu, Yiwu City (CN)

(21) Appl. No.: 19/376,817

(22) Filed: Oct. 31, 2025

Related U.S. Application Data
(60) Provisional application No. 63/716,536, filed on Nov. 5, 2024.

(51) Int. Cl. H10F 71/00; H10F 19/90

(52) U.S. Cl. CPC H10F 71/137; H10F 19/904; H10F 19/908

(57) ABSTRACT

Disclosed is a method for manufacturing a back contact cell assembly, including: providing a plurality of cells, wherein each of the cells has a front surface and a back surface opposite to each other; the back surface has a first doped layer and a second doped layer having opposite doping polarities; and the first doped layer and the second doped layer extend in a first direction and are alternately distributed in a second direction, the first direction intersecting with the second direction; circumferentially arranging the cells multiple times at an outer periphery of a mandrel in a first peripheral placement direction, so as to obtain a first cell preform having multiple turns of cell groups, adjacent cell groups being distributed at intervals in a height direction of the mandrel; winding a solder ribbon at the outer periphery of the first cell preform, so that the solder ribbon is in contact with each cell, and the angle between the winding direction of the solder ribbon and the first peripheral placement direction is an acute angle; and segmenting the solder ribbon into a plurality of sub-solder ribbons along a target position, so that each sub-solder ribbon is connected to the first doped layer of a different one of the cells and the second doped layer of an adjacent one of the cells, and the plurality of cells are connected by means of the sub-solder ribbon to form a cell string.

### CROSS-REFERENCE TO RELATED APPLICATION

This application claims priority to U.S. Provisional Application Ser. No. 63/716,536, filed Nov. 5, 2024, which is incorporated by reference herein in its entirety.

### TECHNICAL FIELD

The present application relates to the technical field of solar cells, and in particular, to a method for manufacturing a back contact cell assembly.

### BACKGROUND

Currently, a back contact cell refers to a solar cell in which the light-receiving surface has no electrodes, with both positive and negative electrodes being located on the backlight surface of the cell, thereby reducing shielding of the cell by the electrode, increasing a short circuit current of the cell, and improving the energy conversion efficiency of the cell. However, in the prior art, the electrodes and solder ribbons of a back contact cell are all provided on the back surfaces of cells. Due to thermal expansion and contraction, the solder ribbons are displaced relative to the cells, causing the solder ribbons to easily snap or detach from the cells.

### SUMMARY

According to one aspect of the present application, a method for manufacturing a back contact cell assembly is provided, the method including the following steps: providing a plurality of cells, wherein each of the cells has a front surface and a back surface opposite to each other; the back surface has first doped layers and second doped layers having opposite doping polarities; and the first doped layer and the second doped layer extend in a first direction and are alternately distributed in a second direction, the first direction intersecting with the second direction; circumferentially arranging the cells multiple times at an outer periphery of a mandrel in a first peripheral placement direction, so as to obtain a first cell preform having multiple turns of cell groups, adjacent cell groups being distributed at intervals in a height direction of the mandrel; winding a solder ribbon at the outer periphery of the first cell preform, so that the solder ribbon is in contact with each cell, and the angle between the winding direction of the solder ribbon and the first peripheral placement direction is an acute angle; and segmenting the solder ribbon into a plurality of sub-solder ribbons along a target position, so that each sub-solder ribbon is electrically connected to the first doped layer of a different cell and the second doped layer of an adjacent cell, and the plurality of cells are connected by means of the sub-solder ribbon to form a cell string.

In some embodiments, any two adjacent cells in the same turn of cell groups have a same spacing, or at least some of any two adjacent cells in the same turn of cell groups are stacked.

In some embodiments, any two adjacent turns of cell groups have the same spacing.

In some embodiments, obtaining the first cell preform includes: grouping the plurality of cells, and sequentially adsorbing each group of cells to the outer periphery of the mandrel in the first peripheral placement direction, to form the multiple turns of cell groups distributed at intervals in the height direction of the mandrel.

In some embodiments, the mandrel is a drum having a plurality of through holes distributed on a drum wall, the interior of the drum is in communication with a vacuum device, and in cases where the vacuum device is in a working state, the through holes have an adsorption force; and in the step of providing the cells at the outer periphery of the mandrel, the drum is driven by a driving device to rotate in the first peripheral placement direction, so that each cell is adsorbed onto the drum wall sequentially under an action of the adsorption force.

In some embodiments, in the step of winding the solder ribbon around the first cell preform, the drum is driven by the driving device to rotate in the first peripheral placement direction, so that the solder ribbon is driven by the drum to wind sequentially to an outer surface of each turn of the cell groups.

In some embodiments, an angle α between the first peripheral placement direction and the winding direction of the solder ribbon satisfies the following relational expression: 0＜tanα≤D/L; where L is a total length in the first peripheral placement direction between an outer end surface of a first one of the cells in the same cell group and an outer end surface of a last one of the cells in a same turn of cell group, and D is a width of any doped layer of the cells in the second direction.

In some embodiments, minimum vertical distances H1 of portions of the solder ribbon respectively located on the outer peripheries of the adjacent cell groups are equal; and central distances H2 of two adjacent doped layers are equal; H1=H2.

In some embodiments, segmenting the solder ribbon into the plurality of sub-solder ribbons along the target position includes: determining an area between the first cell and the last cell in the first peripheral placement direction in a same turn of cell groups as a first target area, and segmenting the solder ribbon along positions of the solder ribbon corresponding to all of the first target areas, so as to obtain a plurality of second cell preforms, each of the second cell preforms including all of the cells in one turn of the cell groups, and the cells in each of the second cell preforms being distributed in the first direction; and determining a gap between adjacent cells in each turn of the cell groups as a second target area, and segmenting the solder ribbon into the sub-solder ribbons along positions of the solder ribbons corresponding to the plurality of second target areas, so that the sub-solder ribbons extend in a third direction and are alternately distributed in the second direction, and each of the sub-solder ribbons is connected to the first doped layer of a different one of the cells and the second doped layer of an adjacent one of the cells, an angle between the first direction and the third direction being an acute angle.

In some embodiments, the method for manufacturing the back contact cell assembly further includes: adsorbing a current collecting structure to the outer periphery of the mandrel, so that the current collecting structure is located between the first one of the cells and the last one of the cells in the first peripheral placement direction in the same turn of the cell groups.

In some embodiments, a width of the first doped layer is equal to a width of the second doped layer in the second direction.

In some embodiments, the back surface is provided with grid lines, the grid lines include first grid lines and second grid lines, the first grid line and the second grid line extend in the first direction and are alternately distributed in the second direction, the first grid lines are provided on the first doped layer, and the second grid lines are provided on the second doped layer; each of the sub-solder ribbons covers the first grid line of a different one of the cells and the second grid line of an adjacent one of the cells.

In some embodiments, minimum vertical distances H1 of portions of the solder ribbon respectively located on the outer peripheries of the adjacent cell groups are equal; and minimum vertical distances H3 between any adjacent grid lines in the cells are equal; H1=H3.

In some embodiments, in the same turn of cell groups, the first grid line, the second grid line, the first doped layer and the second doped layer are all arranged in parallel.

In some embodiments, the sub-solder ribbon includes a first side surface and a second side surface; the first side surface and the second side surface both extend in a third direction; the first side surface on any of the cells includes a leading portion and a trailing portion; a distance between the grid line and the start segment is greater than a distance between the grid line and the end segment; and an angle between the third direction and the first direction is an acute angle.

In some embodiments, the cells are all rectangular, the cell includes first cells and second cells which are sequentially arranged in the first direction; the cell includes a first edge and a second edge which are distributed in the second direction; the grid line of the first cell nearest to the first edge is the first grid line; and the grid line of the second cell closest to the first edge is the second grid line.

In some embodiments, a distance between the leading portion and the first edge of the cell is less than a distance between the trailing portion and the first edge of the cell.

In some embodiments, the first edge of the cell is arranged in parallel with the doped layer or the grid line.

In some embodiments, the solder ribbon includes a first solder ribbon segment and a second solder ribbon segment located at the outer periphery of each turn of the cell group; and the first solder ribbon segment and the second solder ribbon segment are alternately connected in the winding direction; the first solder ribbon segment covers and is connected to the first doped layer or the first grid line of the first cell and the second doped layer or the second grid line of the second cell; the second solder ribbon segment covers and is connected to the second doped layer or the second grid line of the first cell and the first doped layer or the first grid line of another second cell.

In some embodiments, the solder ribbon is in an elongated shape, and a width of the solder ribbon is less than a spacing between the first grid line and the second grid line of any one of the cells.

### BRIEF DESCRIPTION OF THE DRAWINGS

The accompanying drawings, constituting a part of the present application, are used for providing further understanding of the present application, and the illustrative embodiments of the present application and illustrations thereof are used to explain the present application, rather than constitute inappropriate limitation on the present application. In the accompanying drawings:

FIG. 1 is a schematic flowchart of a method for manufacturing a back contact cell assembly according to an embodiment of the present application;

FIG. 2 is a schematic top view of a cell provided in a method for manufacturing a back contact cell assembly according to an embodiment of the present application;

FIG. 3 is a schematic top view of another cell provided in a method for manufacturing a back contact cell assembly according to an embodiment of the present application;

FIG. 4 is a side structural schematic diagram after cells are provided on the outer periphery of a mandrel in a method for manufacturing a back contact cell assembly according to an embodiment of the present application;

FIG. 5 is another side structural schematic diagram after cells are provided on the outer periphery of a mandrel in a method for manufacturing a back contact cell assembly according to an embodiment of the present application;

FIG. 6 is a side structural schematic diagram after solder ribbons are provided on the outer periphery of the mandrel shown in FIG. 4;

FIG. 7 is another side structural schematic diagram after solder ribbons are provided on the outer periphery of the mandrel shown in FIG. 5;

FIG. 8 is a structural schematic diagram of the other side after current collecting strips are provided on the outer periphery of the mandrel;

FIG. 9 is a partial planar structural schematic diagram of a back contact cell assembly obtained by means of a method for manufacturing a back contact cell assembly according to an embodiment of the present application;

FIG. 10 is another partial planar structural schematic diagram of a back contact cell assembly obtained by means of a method for manufacturing a back contact cell assembly according to an embodiment of the present application;

FIG. 11 is still another partial planar structural schematic diagram of a back contact cell assembly obtained by means of a method for manufacturing a back contact cell assembly according to an embodiment of the present application;

FIG. 12 is yet another partial planar structural schematic diagram of a back contact cell assembly obtained by means of a method for manufacturing a back contact cell assembly according to an embodiment of the present application;

FIG. 13 is a modular structural schematic diagram of a back contact cell assembly obtained by means of a method for manufacturing a back contact cell assembly according to an embodiment of the present application;

FIG. 14 is a schematic structural diagram of a photovoltaic system according to an embodiment of the present application.

### Description of Reference Signs:

100, back contact cell assembly; 10, cell; 11, front surface; 12, back surface; 121, first grid line; 122, second grid line; 123, first doped layer; 124, second doped layer; 13, first edge; 14, second edge; 101, first cell; 102, second cell; 110, mandrel; 120, cell group; 20, sub-solder ribbon; 201, solder ribbon; 21, first solder ribbon; 210, first solder segment; 22, second solder ribbon; 220, second solder ribbon segment; 23, first side surface; 231, leading portion; 232, trailing portion; 24, second side surface; 30, current collecting structure; 200, cell string; 300, photovoltaic system.

### DETAILED DESCRIPTION OF THE EMBODIMENTS

To make the objectives, technical solutions, and advantages of the present application clearer, the present application is further described in details below in combination with the drawings and embodiments. Examples of the embodiments will be illustrated in the accompanying drawings, wherein throughout the description, same or similar reference numerals represent same or similar elements or elements with same or similar functions. The embodiments described below with reference to the accompanying drawings are illustrative, and are intended to illustrate the present application, and shall not be understood as limiting the present application. In addition, it should be understood that the specific embodiments described herein are only used to explain the present application, and are not intended to limit the present application.

In the description of the present disclosure, it should be understood that, orientations or position relationships indicated by terms such as “length”, “width”, "upper", "lower", "left", "right", “horizontal”, “top”, “bottom” and the like are orientations or position relationships based on accompanying drawings and are only for the convenience of illustration of the specification and simplicity of illustration, rather than explicitly or implicitly indicate that apparatuses or components referred to herein must have a certain direction or be configured or operated in a certain direction and therefore cannot be understood as limitations to the present application.

In addition, the terms "first" and "second" are only used for descriptive purposes, and cannot be understood as indicating or implying relative importance or implicitly indicating the number of indicated technical features. Thus, features defined by "first" and "second" may explicitly or implicitly include one or more of the features. In the description of the present application, "a plurality of" refers to two or more than two, unless specified otherwise.

In the description of the present application, it should be noted that, unless otherwise specified or defined, the terms such as "mount", "connected” and "connection” should be understood in a broad sense, for example, the connection may be a fixed connection, or a detachable connection, or an integral connection; may be a mechanical connection, may also be an electrical connection or may be an intercommunication; and may be a direct connection, an indirect connection through a medium, or a communication connection between two components or an interaction connection between two components. For those of ordinary skill in the art, the specific meanings of the above terms in the present application can be understood according to specific situations.

In the present application, unless specified or limited otherwise, a first feature being "above" or "below" a second feature may include a direct contact between the first feature and the second feature, and may also include another feature contact between the first feature and the second feature rather than a direct contact. In addition, the first feature being "above", "over", and "on" the second feature includes the first feature being right above and obliquely above the second feature or only refers to the first feature being at a higher horizontal level than the second feature. The first feature being "below", "underneath", and "under" the second feature includes the first feature being right below and obliquely below the second feature or only refers to the first feature being at a lower horizontal level than the second feature.

The following disclosure provides many different embodiments or examples for implementing different structures of the present application. In order to simplify the disclosure of the present application, components and settings of specific examples are described below. Of course, they are merely examples and are not intended to limit the present application. Furthermore, the present application may repeat reference numerals and/or reference letters in different examples for the purpose of simplicity and clarity, and does not in itself indicate a relationship between the various embodiments and/or arrangements discussed. In addition, the present application provides examples of various specific processes and materials, but those skilled in the art will recognize the application of other processes and/or the use of other materials.

In the related art, a solar cell is a semiconductor device which directly converts the energy of sunlight into electric energy. A solar cell utilizes a photovoltaic effect to excite electrons by absorbing photons, and exports these electrons by a built-in electric field to generate a current. A back contact cell refers to a solar cell in which the light-receiving surface has no electrodes, with both positive and negative electrodes being located on the backlight surface of the cell, thereby reducing shielding of the cell by the electrode, increasing a short circuit current of the cell, and improving the energy conversion efficiency of the cell. However, in the prior art, the electrodes and solder ribbons of a back contact cell are all provided on the back surfaces of cells. Due to thermal expansion and contraction, the solder ribbons are displaced relative to the cells, causing the solder ribbons to easily snap or detach from the cells. In the embodiments of the present application, the solder ribbon and the doped layer can be obliquely arranged at an acute angle, so as to increase the contact area between the solder ribbon and the cell, thereby increasing the electric contact area between the solder ribbon and the doped layer, and improving the conductive efficiency from the doped layer to the solder ribbon. Furthermore, the inclined arrangement of the solder ribbon can alleviate the problem of stress concentration, so as to ensure the stable connection between the solder ribbon and the cell.

According to an embodiment of the present application, provided is a method for manufacturing a back contact cell assembly, the method including the following steps: providing a plurality of cells, wherein each of the cells has a front surface and a back surface opposite to each other; the back surface has a first doped layer and a second doped layer having opposite doping polarities; and the first doped layer and the second doped layer extend in a first direction and are alternately distributed in a second direction, the first direction intersecting with the second direction; circumferentially arranging the cells multiple times at the outer periphery of a mandrel in a first peripheral placement direction, so as to obtain a first cell preform having multiple turns of cell groups, adjacent cell groups being distributed at intervals in the height direction of the mandrel; winding a solder ribbon at the outer periphery of the first cell preform, so that the solder ribbon is in contact with each cell, and the angle between the winding direction of the solder ribbon and the first peripheral placement direction is an acute angle; and segmenting the solder ribbon into a plurality of sub-solder ribbons along a target position, so that each sub-solder ribbon is connected to the first doped layer of a different cell and the second doped layer of an adjacent cell, and the plurality of cells are connected by means of the sub-solder ribbon to form a cell string, i.e. each sub-solder ribbon is connected to only two cells, and separation points are arranged in an intersecting manner.

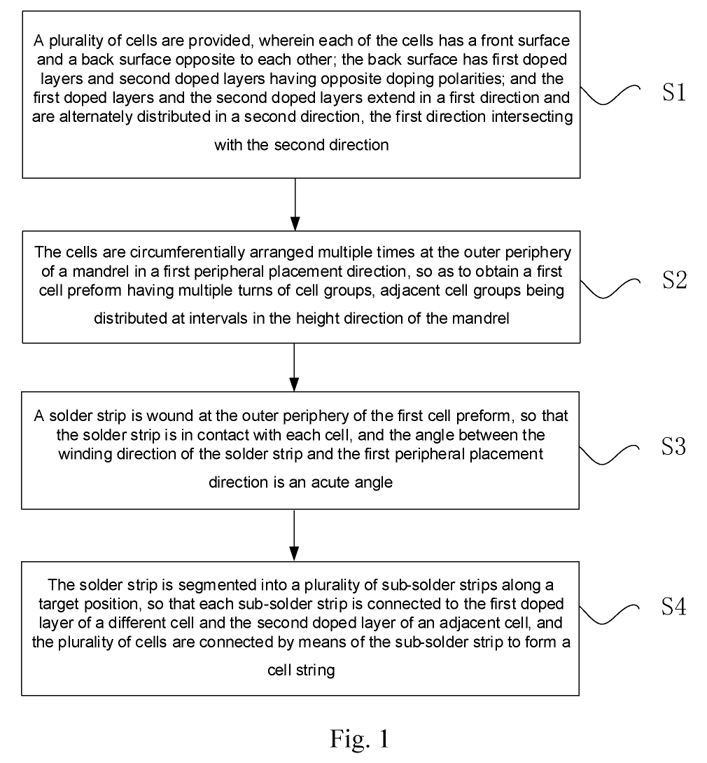

FIG. 1 is a flowchart according to an embodiment of the present application. As shown in FIG. 1, the manufacturing method includes the following steps:

S1, a plurality of cells are provided, wherein each of the cells has a front surface and a back surface opposite to each other; the back surface has a first doped layer and a second doped layer having opposite doping polarities; and the first doped layer and the second doped layer extend in a first direction and are alternately distributed in a second direction, the first direction intersecting with the second direction;

S2, the cells are circumferentially arranged multiple times at the outer periphery of a mandrel in a first peripheral placement direction, so as to obtain a first cell preform having multiple turns of cell groups, adjacent cell groups being distributed at intervals in the height direction of the mandrel;

S3, a solder ribbon is wound at the outer periphery of the first cell preform, so that the solder ribbon is in contact with each cell, and the angle between the winding direction of the solder ribbon and the first peripheral placement direction is an acute angle; and

S4, the solder ribbon is segmented into a plurality of sub-solder ribbons along a target position, so that each sub-solder ribbon is connected to the first doped layer of a different cell and the second doped layer of an adjacent cell, and the plurality of cells are connected by means of the sub-solder ribbon to form a cell string.

In the described method, a plurality of cells can be connected in series using only one solder ribbon, the process is simple and easy to implement; and the solder ribbon and the doped layer can be obliquely arranged at an acute angle, so as to increase the contact area between the solder ribbon and the cell, thereby increasing the electric contact area between the solder ribbon and the doped layer, and improving the conductive efficiency from the doped layer to the solder ribbon. Furthermore, the inclined arrangement of the solder ribbon can alleviate the problem of stress concentration, so as to ensure the stable connection between the solder ribbon and the cell.

Hereinafter, exemplary embodiments of a method of manufacturing a back contact cell assembly according to the present application will be described in more details with reference to the accompanying drawings. However, these exemplary embodiments may be embodied in many different forms and should not be construed as limited to the embodiments set forth herein. It should be understood that these embodiments are provided to make the disclosure of the present application thorough and complete, and to fully convey the concepts of these exemplary embodiments to those skilled in the art.

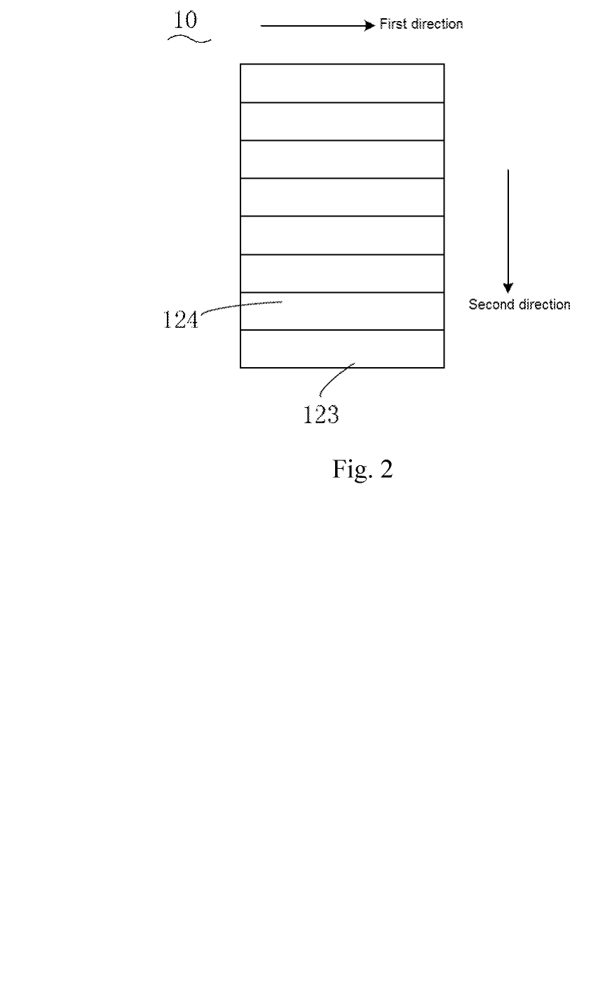

First, step S1 is performed. As shown in FIG. 2, a plurality of cells 10 are provided, wherein each of the cells 10 has a front surface and a back surface opposite to each other; the back surface has a first doped layer 123 and a second doped layer 124 having opposite doping polarities; and the first doped layer 123 and the second doped layer 124 extend in a first direction and are alternately distributed in a second direction, the first direction intersecting with the second direction. It should be noted that, although not shown in FIG. 2, there may be a gap between adjacent doped layers.

Specifically, the front surface 11 of the cell 10 is configured to receive light, the back surface 12 of the cell 10 includes a plurality of first doped layers 123 and second doped layers 124 disposed alternately, and both the first doped layers 123 and the second doped layers 124 extend along the first direction to form a photocurrent.

It should be noted that the present application does not limit the doping types of the first doped layer 123 and the second doped layer 124, for example, the first doped layer 123 and the second doped layer 124 may be respectively a P-type doped layer and an N-type doped layer; or the first doped layer 123 is an N-type doped layer, and the second doped layer 124 may be a P-type doped layer, as long as the polarities of the two are opposite, so as to meet different requirements. In some embodiments, the first doped layer 123 can be a P-type polysilicon layer, a P-type amorphous silicon layer, and a P-type microcrystalline silicon layer, which is not specifically limited herein. By the same reasoning, the second doped layer 124 may be an N-type polysilicon layer, an N-type amorphous silicon layer and an N-type microcrystalline silicon layer, which is not specifically limited herein. When the first doped layer 123 is a P-type doped layer and the second doped layer 124 is an N-type doped layer, a P-type grid line can be further provided on the first doped layer 123, and an N-type grid line can be further provided on the second doped layer 124, which is not specifically limited herein.

In the cell provided by the embodiment of the present application, P-type doping refers to doping of Group III elements, including elements such as boron, aluminum, gallium, indium, and thallium; N-type doping refers to doping of Group V elements, including elements such as nitrogen, phosphorus, arsenic, antimony, and bismuth, which is not specifically limited herein.

In addition, in some implementations, the first doped layer 123 and the second doped layer 124 can also be co-doped, for example, N-type doping may also include a small amount of P-type doping elements. The content of the N-type doping element in the second doped layer 124 is higher than 20% of the content of the P-type doping element, so as to ensure that the second doped layer has a polarity opposite to that of the first doped layer 123.

In the cell provided by the embodiment of the present application, as shown in FIG. 2, the first direction and the second direction may be vertical directions. In this case, the cell 10 may be rectangular, and the first direction and the second direction are also edge directions of the cell 10, so as to utilize the area of the cell 10 to the maximum extent.

In the embodiments of the present application, the types of the cells 10 are not limited, so as to satisfy different requirements. For example, the cell 10 may be a gridless type, achieving current conduction by means of direct connection between the solder ribbon and the doped layer. In addition, in the implementations of the present application, the doped layer of the cell 10 has a uniform width in the second direction.

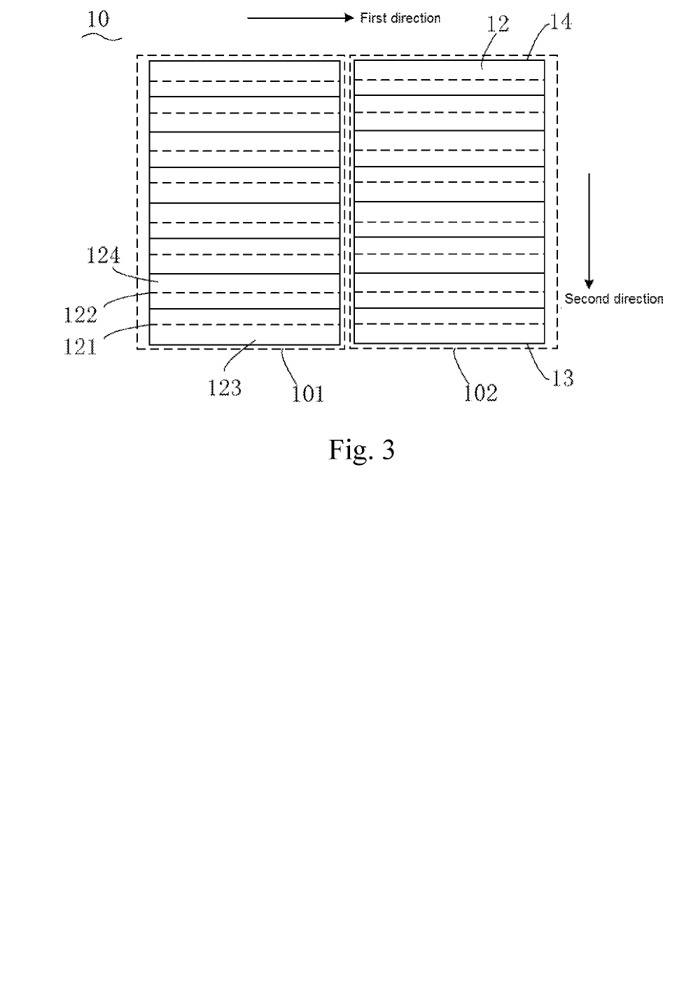

Please refer to FIG. 3, in some optional embodiments, the back surface 12 of the cell 10 is provided with first grid lines 121 and second grid lines 122; the first grid line 121 and the second grid line 122 extend in the first direction and are alternately distributed in the second direction; the first grid line 121 is provided on the first doped layer 123; and the second grid line 122 is provided on the second doped layer 124. In this way, the first doped layer 123 and the second doped layer 124 can conduct a current by means of the first grid line 121 and the second grid line 122; and the subsequently segmented sub-solder ribbons cover the first grid line 121 of the cell 10 and the second grid line 122 of the adjacent cell 10, so that the current can be collected and electrically conducted by means of the sub-solder ribbons.

Specifically, as shown in FIG. 3, the first grid lines 121 and the second grid lines 122 are alternately distributed on the back surface 12 of the cell 10, so as to ensure the uniformity of current collection and conduction, and reduce current loss. The first grid lines 121 are independently provided on the first doped layer 123, and the second grid lines 122 are independently provided on the second doped layer 124, thereby avoiding interference of grid lines on the same doped layer, and improving the current conduction efficiency. The subsequently segmented sub-solder ribbons cover the first grid lines 121 and the second grid lines 122 of the adjacent cell 10, and current collection of the plurality of cells 10 is realized by the sub-solder ribbons, thereby ensuring the efficient conduction of current.

Further, the spacing between the first grid line 121 and the second grid line 122 is adjusted flexibly according to practical requirements. The first grid lines 121 and the second grid lines 122 can be arranged at equal intervals, and the equal intervals can ensure that currents are uniformly distributed, thereby improving the overall efficiency of the back contact cell assembly 100. The unequal spacing arrangement can optimize a current conduction path for a specific application scenario, and reduce problems of local overheating or excessive resistance. A combination of partially equal-spacing and partially non-equal-spacing arrangements can leverage the advantages of both, allowing for flexible adjustment based on specific requirements to optimize the performance of the back contact cell assembly 100.

Please refer to FIG. 3, in some optional embodiments, the cells 10 are all rectangular, the cell 10 includes first cells 101 and second cells 102 which are sequentially arranged in the first direction; the cell 10 includes a first edge 13 and a second edge 14 which are distributed in the second direction; the grid line of the first cell 101 nearest to the first edge 13 is the first grid line; and the grid line of the second cell 102 closest to the first edge 13 is the second grid line 122. Thus, it can be ensured that each grid line is covered by a subsequently obtained sub-solder ribbon. Furthermore, the polarities of the grid lines on the same straight line between two adjacent cells 10 are opposite, so that the sub-solder ribbon may be connected in series to the first cell 101 and the second cell 102.

Specifically, the cell 10 is rectangular, which facilitates mass production and arrangement, and improves space utilization. The cell 10 has a first edge 13 and a second edge 14 distributed in the second direction, facilitating the reasonable arrangement of the grid lines and the collection of the current.

In the implementations of the present application, the shape of the cell 10 is not limited, so as to meet different requirements. For example, the cell 10 may be a rectangular or square full-size cell 10. Then, the square full-size cell 10 is designed to correspond to a single rectangular cell 10 or to a single segmented cell 10 piece (such as a half-segmented piece or a third-segmented piece). The main features of such cell 10 are that the front surface 11 has no grid lines or electrode structures, and the positive and negative electrode grid lines are sequentially and alternately distributed on the back surface 12 of the cell 10. In addition, in the implementations of the present application, the number of the first grid lines 121 and second grid lines 122, as well as their individual size ranges and the spacing between adjacent grid lines, are also not limited, as long as the grid lines can be covered by the subsequently segmented sub-solder ribbons 20, so as to meet different requirements.

Exemplarily, the first grid line 121 may be a positive electrode, and the second grid line 122 may be a negative electrode. Certainly, they may be reversed in other embodiments, that is to say, the first grid line 121 may be a negative electrode, and the second grid line 122 may be a positive electrode, which is not specifically limited herein. The alternating distribution of the first grid lines 121 and the second grid lines 122, along with their precise connection to the solder ribbon, enables more effective collection and transmission of the current, reducing electrical losses in the fingers.

Please refer to FIGS. 2 and 3, in some optional embodiments, the first edge 13 of the cell 10 is arranged parallel to the doped layers or the grid lines. In this way, the first edge 13 and the second edge 14 of the cell 10 may extend in a first direction, which is the same as an extending direction of the doped layers or the grid lines, so that the cell 10 may be in a rectangular shape, which facilitates mass production and arrangement, and improves space utilization.

It can be understood that the terms "first" and "second" in the first cell 101 and the second cell 102 are relative concepts, meaning that the two back-contact cells are different. For example, in the example of FIG. 3, it is noted that the back contact cell on the left side is the first cell 101, and the back contact cell on the right side is the second cell 102.

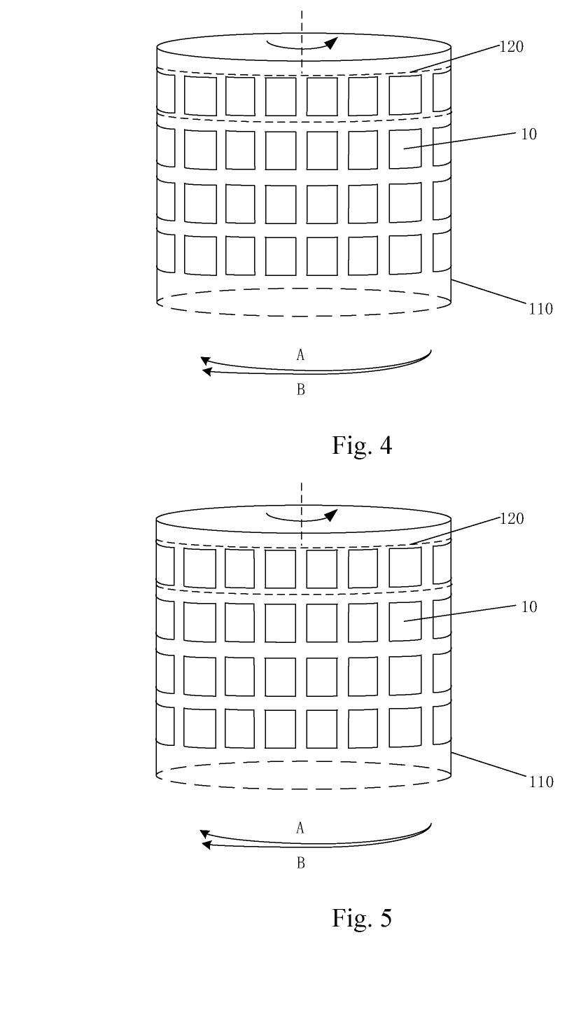

After the step of providing a plurality of cells, step S2 is performed: as shown in FIGS. 4 and 5, the cells 10 are circumferentially arranged multiple times at the outer periphery of a mandrel 110 in a first peripheral placement direction A, so as to obtain a first cell preform having multiple turns of cell groups 120, adjacent cell groups 120 being distributed at intervals in the height direction of the mandrel.

It should be noted that, the first peripheral placement direction A may be a circumferential direction of the mandrel 110, but is not limited to the foregoing direction. For example, an angle between the first peripheral placement direction A and the circumferential direction of the mandrel 110 may be an acute angle, which is not specifically limited in the embodiment of the present application.

In some optional implementations, any two adjacent cells 10 in the same turn of cell groups 120 have the same spacing. By ensuring that the cells 10 in each turn of cell groups 120 have the same spacing, it is advantageous for the cell strings obtained after segmenting the solder ribbon to have the same length, so that after the solder ribbon has been segmented into sub-solder ribbons, it facilitates the formation of the back contact cell assembly using the cell strings connected by the described sub-solder ribbons.

In some optional embodiments, any two adjacent turns of cell groups 120 have the same spacing. By arranging the adjacent cell groups 120 to be at equal intervals, it is beneficial for the solder ribbon to be evenly wound on the surface of the cell 10, so that after the solder ribbon is segmented into sub-solder ribbons, the same number of sub-solder ribbons can be distributed on the cells in each turn of cell groups.

In some optional implementations, the step of obtaining the first cell preform includes: grouping the plurality of cells 10, and sequentially adsorbing each group of cells to the outer periphery of the mandrel 110 in the first peripheral placement direction, to form multiple turns of cell groups 120 distributed at intervals in the height direction of the mandrel 110.

In the foregoing optional implementation, the mandrel 110 is a drum having a plurality of through holes distributed on a drum wall, the interior of the drum is in communication with a vacuum device, and in cases where the vacuum device is in a working state, the through holes have an adsorption force; and the drum is driven by a driving device to rotate in the first peripheral placement direction, so that each cell 10 is adsorbed onto the drum wall sequentially under the action of the adsorption force.

In the foregoing optional implementation, after the cell 10 is provided at the outer periphery of the drum to form multiple turns of the cell groups 120, the drum may also be driven by the driving device to rotate in the first peripheral placement direction A, so that the solder ribbon is driven by the drum to wind sequentially to the outer surface of each turn of the cell groups 120.

It should be noted that, in order to ensure that the cells 10 can be firmly adsorbed to the outer periphery of the drum, the through holes may be distributed evenly in a large quantity on the wall of the drum, so that the cells 10 cover the plurality of through holes under the action of the adsorption force generated inside the drum, and the adsorption force of the plurality of through holes can firmly adsorb the cells 10 to the outer periphery of the drum.

It should be understood that, the cell group 120 may include two cells 10, three cells 10 or more cells 10. Specifically, the number of the cells 10 that need to be connected in series by the solder ribbon may be determined according to an actual usage situation. In addition, in the embodiments of the present application, the size and type of the cells 10 are not limited, and the specifications and sizes of adjacent cells 10 may be the same or different, so as to meet different requirements.

In the implementations of the present application, the specific arrangement manner of the adjacent cells 10 is not limited, so as to meet different requirements. In one embodiment, the edges of two adjacent cells 10 are at least partially stacked together; and in another embodiment, two adjacent cells 10 may be spaced apart. The spacing between two adjacent solar cells 10 is within an appropriate range, which can avoid the issues of limited operating space and increased soldering difficulty caused by excessively small spacing, and can also prevent the waste of assembly space and increased costs resulting from excessively large spacing.

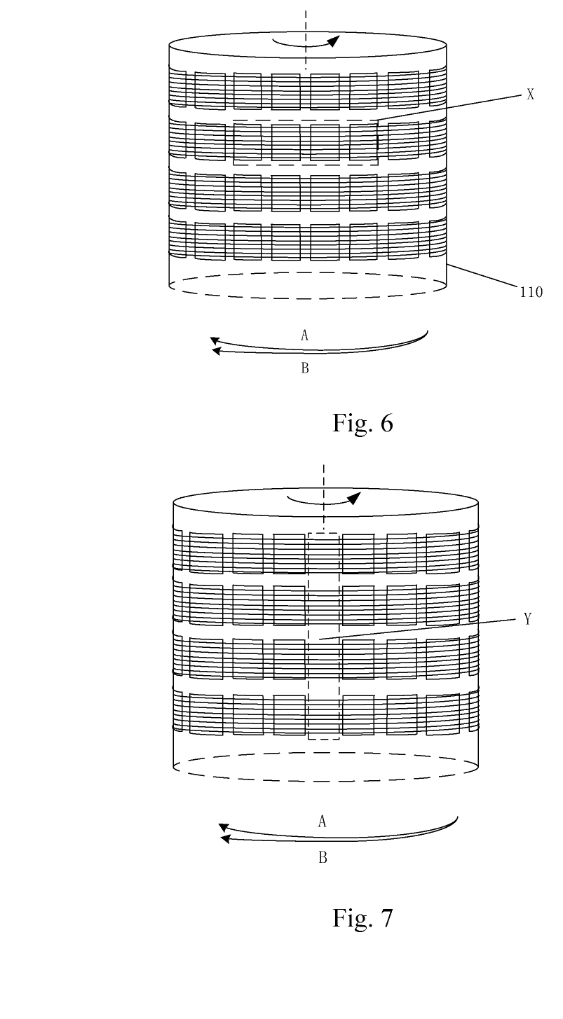

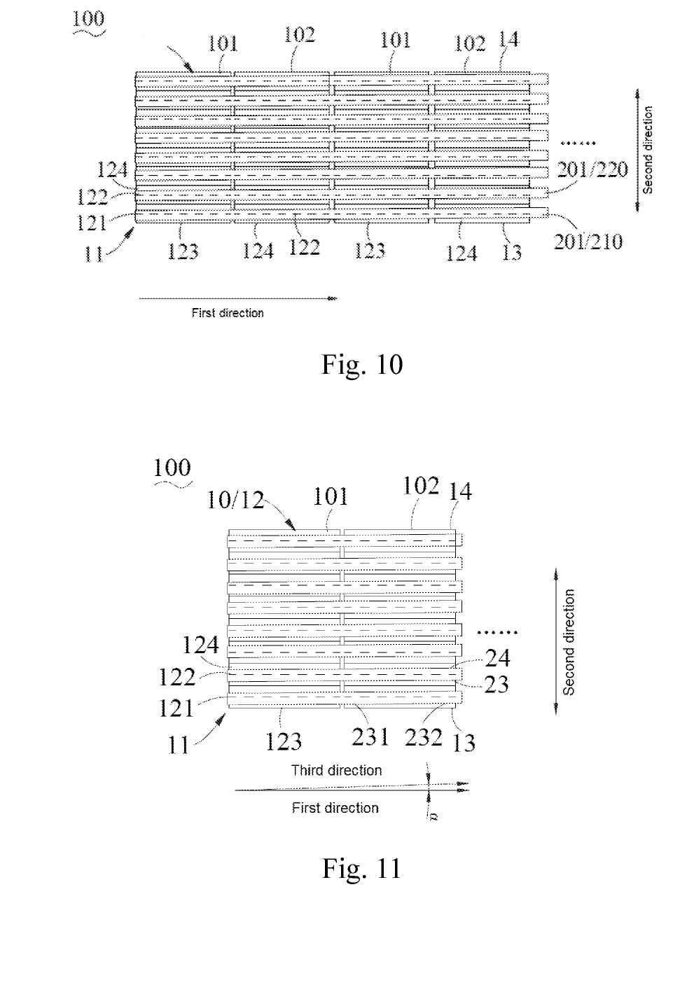

After the first cell preform having multiple turns of cell groups 120 is arranged on the outer periphery of the mandrel 110, step S3 is performed: as shown in FIGS. 6-10, a solder ribbon 201 is wound at the outer periphery of the first cell preform, and the angle between the winding direction B of the solder ribbon 201 and the first peripheral placement direction is an acute angle, so that the solder ribbon 201 is in contact with each cell 10, FIGS. 9 and 10 are partial schematic diagrams of the area X in FIG. 6.

In step S3, the winding direction B of the solder ribbon 201 is actively set to be in an acute angle to the peripheral placement direction of the cell 10 on the outer periphery of the mandrel 110, which can reduce the process difficulty of the back contact cell assembly 100, lower the alignment requirements during the soldering process, improve the fault tolerance and precision of soldering, and reduce the manufacturing complexity. The oblique arrangement is easier to operate by an automation device, improves production efficiency, reduces manual intervention, and reduces production costs. The design of the solder ribbon tilted at an acute angle helps to disperse mechanical stress, reduce stress concentration at the soldering points, and improve the reliability and durability of the soldering points.

In some optional implementations, an angle α between the first peripheral placement direction A and the winding direction B of the solder ribbon satisfies the following relational expression: 0＜tanα≤D/L; where L is a total length in the first peripheral placement direction A between an outer end surface of a first one of the cells 10 in the same cell group and an outer end surface of a last one of the cells 10 in the same cell group, and D is a width of any doped layer of the cells 10 in the second direction.

In the foregoing optional implementation, the inclination angle of the solder ribbon 201 may be obtained according to the required length of the cell string 200, and the angle adjustment may be performed for cell strings 200 of different lengths and different types, so that one solder ribbon 201 may completely cover the doped layers on the same straight line of the plurality of cells 10. In this way, the manufacturing process can be facilitated; after the solder ribbon 201 is segmented to connect the plurality of cells 10 in series, the solder ribbon 201 is selectively cut by laser to form cell strings 200 in pairs.

Specifically, the inclination angle of the solder ribbon 201 is flexibly adjusted according to the required length of the cell string 200 and the width of the doped layer, so as to adapt to specific requirements of different cell strings 200 and ensure that the solder ribbon 201 can completely cover the doped layer. Then, by precisely calculating the angle α, the solder ribbon 201 can extend along a straight line when covering the doped layers, thereby improving the soldering efficiency and consistency. One solder ribbon 201 may completely cover the doped layers of the plurality of cells 10 on the production line of the process, simplifying the soldering process, reducing the soldering steps, and improving the production efficiency. After the solder ribbon 201 is segmented to connect the plurality of cells 10 in series, the solder ribbon 201 is selectively cut by laser to form cell strings 200 in pairs. This method is efficient and accurate, and reduces the complexity in the production process.

Exemplarily, the required cell string 200 consists of 9 cells 10 evenly distributed in the first direction, i.e., each turn of cell groups circumferentially arranged on the outer periphery of the mandrel in the first peripheral placement direction has 9 cells 10, and L is the distance between the farthest ends of 9 cells 10. On the basis of this length and the width of the doped layer in the second direction, the tilt angle α is calculated, allowing the solder ribbon to be obliquely arranged at an angle α.

In the implementations of the present application, the range of the angle between the first peripheral placement direction A of the cell 10 and the winding direction B of the solder ribbon is not defined, so as to meet different requirements. In this way, the adjustment can be made according to the lengths of different required cell strings 200 and the width of the doped layer in the second direction.

Still further, the widths of the first doped layer 123 and the second doped layer 124 in the second direction are equal. In this way, the first doped layer 123 and the second doped layer 124 may be distributed, and the solder ribbon 201 may be evenly provided on the back surface 12, so that the solder ribbon 201 may be separately provided on a corresponding doped layer after being segmented. The doped layers may be evenly distributed, and the solder ribbon 201 may evenly cover the back surface 12, so as to ensure an even conduction of the current.

Still further, the minimum vertical distances H1 of portions of the solder ribbon 201 respectively located on the outer peripheries of the adjacent cell groups are equal; and the central distances H2 of two adjacent doped layers are equal; H1=H2. In this way, after the doped layers are evenly distributed on the back surface 12 of the cell 10, the solder ribbons 201 may also be evenly distributed on the back surface 12 of the cell 10. After the solder ribbon 201 is segmented into sub-solder ribbons, the sub-solder ribbons and the doped layers may be accurately arranged correspondingly, ensuring that each doped layer can effectively connect the sub-solder ribbons.

Still further, in cases where the back surface 12 of the cell 10 is provided with grid lines, the minimum vertical distances H3 between any adjacent grid lines in the cells 10 are equal; H1=H3. In this way, after the grid lines are evenly distributed on the back surface 12 of the cell 10, the solder ribbons 201 may also be evenly distributed on the back surface 12 of the cell 10. After the solder ribbon 201 is segmented into sub-solder ribbons, the sub-solder ribbons and the grid lines may be accurately arranged correspondingly, ensuring that each grid line can effectively connect the sub-solder ribbons.

In addition, in the implementations of the present application, the center distances being equal means that "the distance between structure centers of two adjacent structures is equal to the distance between structure centers of another two adjacent structures". In the process preparation, "equal" can allow an error ratio between 0.9 and 1.1. In other words, when the nominal center distance is 1, the maximum error distance can be up to 1.1 times the nominal distance, and the minimum error distance can be 0.9 times the nominal distance.

In the implementations of the present application, the minimum vertical distance H1 between the solder ribbons 201 respectively located on the outer peripheries of adjacent cell groups is not limited, so as to meet different requirements. For example, the minimum vertical distance H1 between the solder ribbons 201 respectively located on the outer peripheries of adjacent cell groups may be ≥100μm, exemplarily, H1 = 300 μm.

In cases where the back surface 12 of the cell 10 is provided with first grid lines 121 and second grid lines 122, in some optional embodiments, the solder ribbon 201 is in an elongated shape, and a width of the solder ribbon 201 is less than a spacing between the first grid line 121 and the second grid line 122. In this way, when the solder ribbons 201 are provided on the cells 10, it avoids the issue of the solder ribbons 201 simultaneously crossing two grid lines of a cell 10, which could cause a short circuit.

Specifically, the width of the solder ribbon 201 is designed to be less than the spacing between the first grid line 121 and the second grid line 122, so as to ensure that two adjacent grid lines are not crossed and connected simultaneously when the solder ribbons 201 are arranged. By controlling the width of the solder ribbon 201, the solder ribbon 201 is prevented from crossing two grid lines of one cell 10 at the same time, thereby preventing the issue of a short circuit and ensuring the safety and stable operation of the cell 10.

Please refer to FIGS. 9 and 10, in some optional embodiments, the solder ribbon 201 includes a first solder ribbon segment 210 and a second solder ribbon segment 220 located at the outer periphery of each turn of the cell group; and the first solder ribbon segment 210 and the second solder ribbon segment 220 are alternately connected in the winding direction; the first solder ribbon segment 210 covers and is connected to the first doped layer 123 or the first grid line 121 of the first cell 101 and the second doped layer 124 or the second grid line 122 of the second cell 102; the second solder ribbon segment 220 covers and is connected to the second doped layer 124 or the second grid line 122 of the first cell 101 and the first doped layer 123 or the first grid line 121 of another second cell 102. In this way, after the solder ribbon 201 is segmented into the solder ribbons, the first solder ribbon segment 210 and the second solder ribbon segment 220 cooperate successively to form a cell string by connecting the plurality of first cells 101 and the plurality of second cell 102 in series.

After the solder ribbon 201 is wound around the outer periphery of the first cell preform, step S4 is performed: as shown in FIGS. 11-13, the solder ribbon is segmented into a plurality of sub-solder ribbons 20 along a target position, so that each sub-solder ribbon 20 is electrically connected to the first doped layer 123 of a different one of the cells 10 and the second doped layer 124 of an adjacent one of the cells 10, and the plurality of cells 10 are connected in series by means of the sub-solder ribbon 20 to form a cell string 200.

Specifically, as shown in FIGS. 5 to 12, an area between the first cell 10 and the last cell 10 in the first peripheral placement direction A in the same turn of cell groups 120 is determined as a first target area Y, and the solder ribbon 201 is segmented along the positions of the solder ribbon 201 corresponding to all of the first target areas Y, so as to obtain a plurality of second cell preforms, each of the second cell preforms including all of the cells 10 in one turn of the cell groups 120, and the cells 10 in each of the second cell preforms being distributed in the first direction; and then a gap between adjacent cells 10 in each turn of the cell groups 120 is determined as a second target area, and the solder ribbon 201 is segmented into the sub-solder ribbons 20 along positions of the solder ribbons 201 corresponding to the plurality of second target areas, so that the sub-solder ribbons 20 extend in a third direction and are alternately distributed in the second direction, and each of the sub-solder ribbons 20 is connected to the first doped layer 123 of a different one of the cells 10 and the second doped layer 124 of an adjacent one of the cells 10, an angle between the first direction and the third direction being an acute angle.

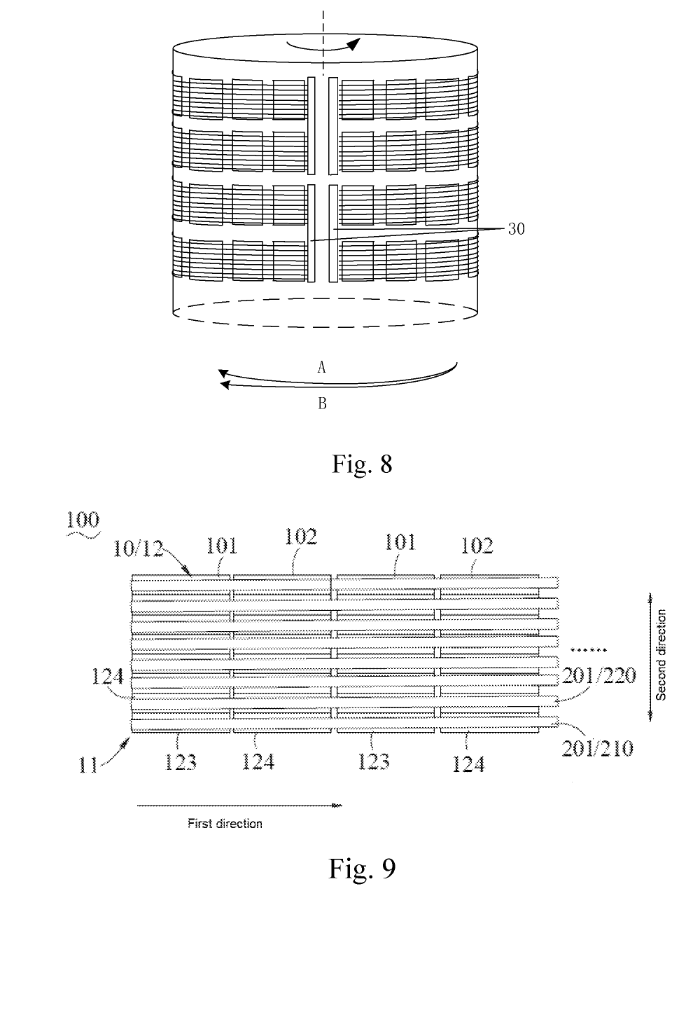

After obtaining the plurality of second cell preforms or segmenting the solder ribbon 201 into the sub-solder ribbons 20, the manufacturing method of the embodiment of the present application can further include: as shown in FIG. 8, adsorbing a current collecting structure 30 to the outer periphery of the mandrel 110, so that the current collecting structure 30 is located between the first one of the cells 10 and the last one of the cells 10 in the first peripheral placement direction A in the same turn of the cell groups 120.

Specifically, the current collecting structure 30 may be configured to connect solder ribbons of the same polarity, so as to form a loop with the cell string 200 to conduct current energy. In the implementations of the present application, the form of the current collecting structure 30 is not limited, so as to meet different requirements. For example, the current collecting structure 30 can be a conductive material such as a wire, a current collecting bar, and a conductive adhesive tape.

After the solder ribbon 201 is segmented into the sub-solder ribbons 20, the first doped layer 123 of the cell 10 and the second doped layer 124 of the adjacent cell 10 may be connected together by means of the sub-solder ribbons 20, and furthermore, the second doped layer 124 of the cell 10 and the first doped layer 123 of another adjacent cell 10 may be connected together by means of the sub-solder ribbons 20. That is to say, the plurality of cells 10 may be connected together in series by the sub-solder ribbons 20 to form the cell strings 200 distributed in the first direction. Certainly, in some implementations, the solder ribbon 20 located at the end portion of the cell string 200 may be connected to only one doped layer, and extends with respect to the cell 10, so as to be connected to the current collecting bar and other structures.

After the solder ribbon 201 is segmented into the sub-solder ribbons 20, the sub-solder ribbons 20 are arranged on at least two cells 10 in a third direction, and electrically connect the first doped layer 123 of the cell 10 and the second doped layer 124 of the adjacent cell 10. The sub-solder ribbons 20 are alternately distributed in the second direction, so as to connect heterogeneous doped layers of adjacent cells 10 to form a cell string 200, wherein the angle between the first direction and the third direction is an acute angle. By obliquely arranging the sub-solder ribbon 20 and the doped layer at an acute angle, the contact area between the sub-solder ribbon 20 and the cell 10 is significantly increased, thereby improving the electric contact area between the sub-solder ribbon 20 and the doped layer, and enhancing the conductive efficiency. Furthermore, the inclined design of the sub-solder ribbons 20 can effectively alleviate the issue of stress concentration, ensure the stability of the connection between the sub-solder ribbon 20 and the cell 10, and reduce the connection failure caused by mechanical stress or temperature change. The firm connection between the solder ribbons 20 and the doped layers ensures a stable electrical connection between the cells 10, and improves the reliability and service life of the back contact cell assembly 100.

In cases where the back surface 12 of the cell 10 is provided with first grid lines 121 and second grid lines 122, the first grid lines 121 and the second grid lines 122 are alternately distributed on the back surface 12 of the cell 10, the first grid line 121 are independently arranged on the first doped layer 123, and the second grid lines 122 are independently arranged on the second doped layer 124, the sub-solder ribbons 20 cover the first grid lines 121 and the second grid lines 122 of the adjacent cell 10, and current collection between the plurality of cells 10 is realized by the sub-solder ribbons 20, ensuring the efficient conduction of the current.

Specifically, during the manufacturing process, one solder ribbon 201 may be simultaneously provided on the same straight line of a plurality of cells 10, and then may be disconnected at a target position, so as to ensure that the segmented solder ribbon 20 can connect the first grid lines 121 and the second grid lines 122 of adjacent cells 10. For example, the sub-solder ribbons 20 can be connected to the first grid line 121 of the first cell 10 and the second grid line 122 of the second cell 10, and then be disconnected at the end of the second grid line 122 of the second cell 10 away from the first cell 10. By the same reasoning, the sub-solder ribbons 20 can be connected to the first grid line 121 of the second cell 10 and the second grid line 122 of the third cell 10, and then be disconnected at the end of the second grid line 122 of the third cell 10 away from the second cell 10. By analogy, a continuous cell string 200 can be formed.

Further, in the manufacturing process of the cell string 200, the sub-solder ribbons 20 can cover grid lines of a plurality of cells 10 on the same straight line at one time along a third direction, thereby improving the soldering efficiency, reducing soldering steps and time, and being suitable for large-scale production. The design that the sub-solder ribbons 20 are attached to the grid lines after being inclined at a certain angle facilitates the operation of an automatic device, thereby improving the accuracy and consistency of production. The connection between the solder ribbons 20 and the grid lines increases the mechanical strength and stability of the back contact cell assembly 100, and prolongs the service life.

Still further, the plurality of sub solder ribbons 20 are arranged parallel to each other; the first grid lines 121, the second grid lines 122, the first doped layers 123 and the second doped layers 124 are all arranged in parallel. In this way, the grid lines and the doped layers are all arranged in parallel on the back surface 12 of the cell 10, so that the whole of the cells 10 can be more uniform. The plurality of sub-solder ribbons 20 are arranged in parallel on the back surface 12 of the cell, and are evenly distributed in a direction perpendicular to the third direction, so as to ensure that the spacing between the sub-solder ribbons 20 is consistent, and form a regular layout. Furthermore, the sub-solder ribbons 20 may be arranged to correspond to the grid lines or the doped layers.

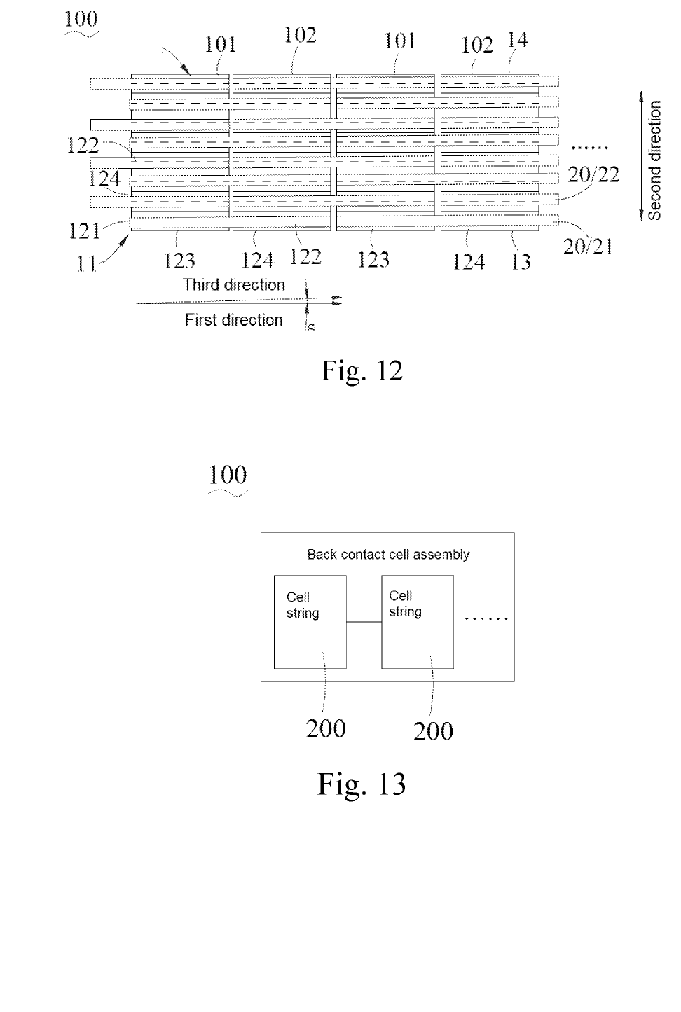

Please refer to FIGS. 11 and 12, in some embodiments, the solder ribbon 20 includes a first side surface 23 and a second side surface 24, both the first side surface 23 and the second side surface 24 extend in a third direction, the first side surface 23 on any of the cells 10 includes a leading portion 231 and a trailing portion 232, and a distance between the grid line and the leading portion 231 is greater than a distance between the grid line and the trailing portion 232.

In this way, the sub-solder ribbons 20 are arranged in the third direction on each of the cells 10, and the sub-solder ribbon 20 is positioned differently from the grid line on the first side surface 23 of any of the cells 10, such that the sub-solder ribbons 20 can cover the grid lines and improve the connection capability with the grid lines.

Specifically, the sub-solder ribbons 20 are also rectangular, the first side surface 23 and the second side surface 24 are both arranged in the third direction, and the sub-solder ribbons 20 are arranged in the third direction, so as to ensure that the sub-solder ribbons 20 cover the grid lines, increase the contact area between the sub-solder ribbons 20 and the grid lines, and improve the current conduction efficiency. The leading portion 231 and the trailing portion 232 of the sub-solder ribbon 20 have different distances from the grid line, ensuring the optimal position of the sub-solder ribbon 20 on the cell 10, and improving the connection capability and stability between the sub-solder ribbon 20 and the grid line.

Please refer to FIGS. 11 and 12, in some optional embodiments, the sub-solder ribbon 20 includes a first solder ribbon 21 and a second solder ribbon 22; the first solder ribbon 21 and the second solder ribbon 22 extend in the third direction and are alternately distributed in the second direction; the first solder ribbon 21 corresponds to the first solder ribbon segment 210 of the sub-solder ribbon in step S3, and the second solder ribbon 22 corresponds to the second solder ribbon segment 220 of the sub-solder ribbon in step S3; the first solder ribbon 21 covers and is connected to the first doped layer 123 or the first grid line 121 of the first cell 101 and the second doped layer 124 or the second grid line 122 of the second cell 102; the second solder ribbon 22 covers and is connected to the second doped layer 124 or the second grid line 122 of the first cell 101 and the first doped layer 123 or the first grid line 121 of another second cell 102. In this way, the first solder ribbon 21 and the second solder ribbon 22 cooperate successively to form a cell string 200by connecting the plurality of first cells 101 and the plurality of second cell 102 in series.

Referring to FIGS. 11 and 12, in some optional embodiments, a distance between the leading portion 231 and the first edge 13 of the cell 10 is less than a distance between the trailing portion 232 and the first edge 13 of the cell 10. In this way, the sub-solder ribbons 20 on the cell 10 are obliquely arranged relative to the edge of the cell 10, the leading portion 231 and the trailing portion have different distances from the first edge 13, and the sub-solder ribbon 20 can cover a corresponding grid line, thereby ensuring that the connection with the grid line is stable.

Specifically, on the same cell 10, the leading portion 231 of the sub-solder ribbon 20 is closer to the first edge 13 of the cell 10, while the trailing portion 232 of the sub-solder ribbon 20 is farther from the first edge 13 of the cell 10. The arrangement of the sub-solder ribbons 20 on the cell 10 causes the sub-solder ribbons 20 to exhibit a tilted posture relative to the first edge 13 of the cell 10. The leading portion 231 and the trailing portion 232 of the sub-solder ribbon 20 cover the corresponding grid lines, so as to ensure the stability of current conduction. Furthermore, the sub-solder ribbons 20 and the cells 10 are obliquely arranged, which increases the contact area between the sub-solder ribbons 20 and the grid lines, and ensures stability and high efficiency of current conduction. The leading portion 231 and the trailing portion 232 of the sub-solder ribbon 20 both cover the grid lines, thereby effectively preventing the sub-solder ribbons 20 from disconnecting from the grid lines, and improving the reliability of the connection. In addition, the sub-solder ribbon 20 is obliquely arranged relative to the edge of the cell 10, so that a contact position between the sub-solder ribbon 20 and a grid line can be flexibly adjusted, thereby adapting to cells 10 of different types and sizes. The obliquely arranged sub-solder ribbons 20 can effectively disperse mechanical stress, reduce solder spot damage caused by stress concentration, and prolong the service life of the back contact cell assembly 100.

Exemplarily, referring to FIGS. 11 to 13, the back contact cell assembly 100 obtained by using the foregoing manufacturing method according to the embodiment of the present application includes cell strings 200 and sub-solder ribbons 20; the cell string 200 includes a plurality of cells 10; the cells 10 have a front surface 11 and a back surface 12 opposite to each other; the back surface 12 is provided with a first doped layer 123 and a second doped layer 124; the first doped layer 123 and the second doped layer 124 extend in the first direction and are alternately distributed in a second direction, the first direction intersecting with the second direction. The sub-solder ribbon 20 are provided on at least two cells 10, and are electrically connected to the first doped layer 123 of the cell 10 and the second doped layer 124 of the adjacent cell 10 respectively; the sub-solder ribbons 20 extend in the third direction and are alternately distributed in the second direction, wherein an angle between the first direction and the third direction is an acute angle, and the doping polarities of the first doped layer 123 and the second doped layer 124 are opposite.

In the back contact cell assembly 100 of the embodiment of the present application, the back contact cell assembly 100 includes cell strings 200 and sub-solder ribbons 20; the cell string 200 includes a plurality of cells 10; the cells 10 have a front surface 11 and a back surface 12 opposite to each other; the back surface 12 is provided with a first doped layer 123 and a second doped layer 124; the first doped layer 123 and the second doped layer 124 extend in the first direction and are alternately distributed in a second direction, the first direction intersecting with the second direction; the sub-solder ribbon 20 are provided on at least two cells 10, and are electrically connected to the first doped layer 123 of the cell 10 and the second doped layer 124 of the adjacent cell 10 respectively; the sub-solder ribbons 20 extend in the third direction and are alternately distributed in the second direction, wherein an angle between the first direction and the third direction is an acute angle, and the doping polarities of the first doped layer 123 and the second doped layer 124 are opposite. In this way, the sub-solder ribbon 20 and the doped layer may be obliquely arranged at an acute angle, so as to increase the contact area between the sub-solder ribbon 20 and the cell 10, thereby increasing the electrical contact area between the sub-solder ribbon 20 and the doped layer, and improving the conduction efficiency from the doped layer to the sub-solder ribbon 20. Furthermore, the inclined arrangement of the sub-solder ribbons 20 can alleviate the problem of stress concentration, so as to ensure the stable connection between the sub-solder ribbon 20 and the cell 10, and improve the stability of the connection between the sub-solder ribbon 20 and the cell 10.

After that, the solder ribbon is segmented into a plurality of sub-solder ribbons along a target position, and a plurality of cells are connected in series by means of the sub-solder ribbons to form a cell string. The manufacturing method in the embodiments of the present application can further include: placing a back adhesive film and a back plate on one side of the cell 10 provided with the sub-solder ribbons 20, so as to form a member to be laminated; the member to be laminated is framed and installed, and a junction box is soldered to form a back contact cell assembly 100.

Exemplarily, a solder ribbon at a target position is cut off by laser cutting or other techniques, so as to form cell strings 200 connected in series; the cell strings 200 are placed between a front plate and a back plate; the cell strings 200 are bonded to the front plate by means of the front adhesive film and bonded to the back plate by means of the back adhesive film; and the back adhesive film and the back plate are located at one side of the cell 10 provided with the sub-solder ribbons 20, so as to form the member to be laminated. Finally, the member to be laminated is framed and installed, and a junction box is soldered to form a back contact cell assembly 100.

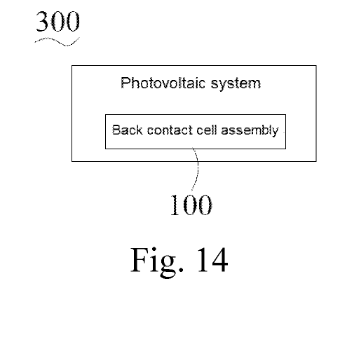

Please refer to FIG. 14, a photovoltaic system 300 provided in an embodiment of the present application includes a back contact cell assembly 100 manufactured according to any one of the above embodiments.

Specifically, as shown in FIGS. 11 to 14, in the back contact cell assembly 100, the method for manufacturing the back contact cell assembly, and the photovoltaic system 300 according to the embodiments of the present application, the back contact cell assembly 100 includes cell strings 200 and sub-solder ribbons 20; the cell string 200 includes a plurality of cells 10; the cells 10 have a front surface 11 and a back surface 12 opposite to each other; the back surface 12 is provided with a first doped layer 123 and a second doped layer 124; the first doped layer 123 and the second doped layer 124 extend in the first direction and are alternately distributed in a second direction, the first direction intersecting with the second direction; the sub-solder ribbon 20 are provided on at least two cells 10, and are electrically connected to the first doped layer 123 of the cell 10 and the second doped layer 124 of the adjacent cell 10 respectively; the sub-solder ribbons 20 extend in the third direction and are alternately distributed in the second direction, wherein an angle between the first direction and the third direction is an acute angle, and the doping polarities of the first doped layer 123 and the second doped layer 124 are opposite. In this way, the sub-solder ribbon 20 and the doped layer may be obliquely arranged at an acute angle, so as to increase the contact area between the sub-solder ribbon 20 and the cell 10, thereby increasing the electrical contact area between the sub-solder ribbon 20 and the doped layer, and improving the conduction efficiency from the doped layer to the sub-solder ribbon 20. Furthermore, the inclined arrangement of the sub-solder ribbons 20 can alleviate the issue of stress concentration, so as to ensure the stable connection between the sub-solder ribbon 20 and the cell 10.

In the present embodiment, the photovoltaic system 300 may be applied in a photovoltaic power plant, such as a surface power station, a rooftop power plant and a floating power plant, and may also be applied to a device or an apparatus that generates power using solar energy, such as a solar power source, a solar street lamp, a solar-powered vehicle, and a solar-integrated building. Certainly, it can be understood that, the application scenarios of the photovoltaic system 300 are not limited thereto, that is, the photovoltaic system 300 may be applied in all fields that need to use solar energy to generate power. Taking a photovoltaic power generation system network as an example, the photovoltaic system 300 may include a photovoltaic array, a combiner box and an inverter; the photovoltaic array may be an array combination of a plurality of back contact cell assemblies 100, for example, the plurality of back contact cell assemblies 100 may form a plurality of photovoltaic arrays, the photovoltaic arrays are connected to the combiner box; and the combiner box may collect currents generated by the photovoltaic arrays, and the collected currents are converted by the inverter into an alternating current required by the utility grid, and then are connected to the utility grid to implement solar power supply.

It should also be noted that the terms "include", "includes", or any other variations thereof are intended to cover a non-exclusive inclusion, so that a process, a method, a commodity, or a device that includes a series of elements not only includes those elements, but also includes other elements that are not explicitly listed, or further includes inherent elements of the process, the method, the commodity, or the device. Without further limitation, an element defined by a sentence "include a ..." does not exclude other same elements existing in a process, a method, a commodity, or a device that includes the element.

The described content merely relates to embodiments of the present disclosure, and is not intended to limit some embodiments of the present disclosure. For those skilled in the art, the present disclosure may have various modifications and variations. Any modifications, equivalent replacements, improvements, etc. made within the spirit and principle of the present disclosure shall belong to the scope of the claims of the present disclosure.

What is claimed is:

1. A method for manufacturing a back contact cell assembly, comprising:
providing a plurality of cells, wherein each of the cells has a front surface and a back surface opposite to each other; the back surface has first doped layers and second doped layers having opposite doping polarities; and the first doped layers and the second doped layers extend in a first direction and are alternately distributed in a second direction, the first direction intersecting with the second direction;
circumferentially arranging the cells multiple times at an outer periphery of a mandrel in a first peripheral placement direction, so as to obtain a first cell preform having multiple turns of cell groups, adjacent cell groups being distributed at intervals in a height direction of the mandrel;
winding a solder ribbon at the outer periphery of the first cell preform, an angle between a winding direction of the solder ribbon and the first peripheral placement direction being an acute angle, so that the solder ribbon contacts each of the cells; and
segmenting the solder ribbon into a plurality of sub-solder ribbons along a target position, so that each sub-solder ribbon is electrically connected to the first doped layer of a different one of the cells and the second doped layer of an adjacent one of the cells, and the plurality of cells are connected in series by means of the sub-solder ribbon to form a cell string.

2. The method for manufacturing the back contact cell assembly according to claim 1, wherein any two adjacent cells in a same turn of cell groups have a same spacing, or at least some of any two adjacent cells in the same turn of cell groups are stacked.

3. The method for manufacturing the back contact cell assembly according to claim 1, wherein any two adjacent turns of cell groups have the same spacing.

4. The method for manufacturing the back contact cell assembly according to claim 1, wherein obtaining the first cell preform comprises:
grouping the plurality of cells, and sequentially adsorbing each group of cells to the outer periphery of the mandrel in the first peripheral placement direction, to form the multiple turns of cell groups distributed at intervals in the height direction of the mandrel.

5. The method for manufacturing the back contact cell assembly according to claim 4, wherein
the mandrel is a drum having a plurality of through holes distributed on a drum wall, the interior of the drum is in communication with a vacuum device, and in cases where the vacuum device is in a working state, the through holes have an adsorption force; and
in the step of providing the cells at the outer periphery of the mandrel, the drum is driven by a driving device to rotate in the first peripheral placement direction, so that each cell is adsorbed onto the drum wall sequentially under an action of the adsorption force.

6. The method for manufacturing the back contact cell assembly according to claim 5, wherein in the step of winding the solder ribbon around the first cell preform, the drum is driven by the driving device to rotate in the first peripheral placement direction, so that the solder ribbon is driven by the drum to wind sequentially to an outer surface of each turn of the cell groups.

7. The method for manufacturing the back contact cell assembly according to claim 1, wherein an angle α between the first peripheral placement direction and the winding direction of the solder ribbon satisfies the following relational expression: 0＜tanα≤D/L;
where L is a total length in the first peripheral placement direction between an outer end surface of a first one of the cells in and an outer end surface of a last one of the cells in a same turn of cell group, and D is a width of any doped layer of the cells in the second direction.

8. The method for manufacturing the back contact cell assembly according to claim 1, wherein minimum vertical distances H1 of portions of the solder ribbon respectively located on the outer peripheries of the adjacent cell groups are equal; and central distances H2 of two adjacent doped layers are equal; H1=H2.

9. The method for manufacturing the back contact cell assembly according to claim 1, wherein segmenting the solder ribbon into the plurality of sub-solder ribbons along the target position comprises:
determining an area between the first cell and the last cell in the first peripheral placement direction in a same turn of cell groups as a first target area, and segmenting the solder ribbon along positions of the solder ribbon corresponding to all of first target areas, so as to obtain a plurality of second cell preforms, each of the second cell preforms comprising all of the cells in one turn of the cell groups, and the cells in each of the second cell preforms being distributed in the first direction; and
determining a gap between adjacent cells in each turn of the cell groups as a second target area, and segmenting the solder ribbon into the sub-solder ribbons along positions of the solder ribbons corresponding to the plurality of second target areas, so that the sub-solder ribbons extend in a third direction and are alternately distributed in the second direction, and each of the sub-solder ribbons is connected to the first doped layer of a different one of the cells and the second doped layer of an adjacent one of the cells, an angle between the first direction and the third direction being an acute angle.

10. The method for manufacturing the back contact cell assembly according to claim 9, further comprising:
adsorbing a current collecting structure to the outer periphery of the mandrel, so that the current collecting structure is located between the first one of the cells and the last one of the cells in the first peripheral placement direction in the same turn of the cell groups.

11. The method for manufacturing the back contact cell assembly according to claim 1, wherein a width of the first doped layer is equal to a width of the second doped layer in the second direction.

12. The method for manufacturing the back contact cell assembly according to claim 1, wherein
the back surface is provided with grid lines, the grid lines comprise first grid lines and second grid lines, the first grid lines and the second grid lines extend in the first direction and are alternately distributed in the second direction, the first grid lines are provided on the first doped layer, and the second grid lines are provided on the second doped layer;
each of the sub-solder ribbons covers the first grid line of a different one of the cells and the second grid line of an adjacent one of the cells.

13. The method for manufacturing the back contact cell assembly according to claim 12, wherein minimum vertical distances H1 of portions of the solder ribbon respectively located on the outer peripheries of the adjacent cell groups are equal; and minimum vertical distances H3 between any adjacent grid lines in the cells are equal; H1=H3.

14. The method for manufacturing the back contact cell assembly according to claim 12, wherein in a same turn of cell groups, the first grid line, the second grid line, the first doped layer and the second doped layer are all arranged in parallel.

15. The method for manufacturing the back contact cell assembly according to claim 12, wherein the sub-solder ribbon comprises a first side surface and a second side surface; the first side surface and the second side surface both extend in a third direction; the first side surface on any of the cells comprises a leading portion and a trailing portion; a distance between the grid line and the start segment is greater than a distance between the grid line and the end segment; and an angle between the third direction and the first direction is an acute angle.

16. The method for manufacturing the back contact cell assembly according to claim 15, wherein the cells are all rectangular, the cell comprises first cells and second cells which are sequentially arranged in the first direction; the cell comprises a first edge and a second edge which are distributed in the second direction; the grid line of the first cell nearest to the first edge is the first grid line; and the grid line of the second cell closest to the first edge is the second grid line.

17. The method for manufacturing the back contact cell assembly according to claim 16, wherein a distance between the leading portion and the first edge of the cell is less than a distance between the trailing portion and the first edge of the cell.

18. The method for manufacturing the back contact cell assembly according to claim 16, wherein the first edge of the cell is arranged in parallel with the doped layer or the grid line.

19. The method for manufacturing the back contact cell assembly according to claim 16, wherein
the solder ribbon comprises a first solder ribbon segment and a second solder ribbon segment located at the outer periphery of each turn of the cell group; and first solder ribbon segments and second solder ribbon segments are alternately connected in the winding direction;
the first solder ribbon segment covers and is connected to the first doped layer or the first grid line of the first cell and the second doped layer or the second grid line of the second cell;
the second solder ribbon segment covers and is connected to the second doped layer or the second grid line of the first cell and the first doped layer or the first grid line of another second cell.

20. The method for manufacturing the back contact cell assembly according to claim 12, wherein the solder ribbon is in an elongated shape, and a width of the solder ribbon is less than a spacing between the first grid line and the second grid line of any one of the cells.
